(19) United States
(12) Patent Application Publication
(10) Pub. No.: US 2026/0271191 A1
(43) Pub. Date: Sep. 10, 2026

(54) WIRING CIRCUIT BOARD

(71) Applicant: NITTO DENKO CORPORATION, Osaka (JP)

(72) Inventors: Shusaku SHIBATA, Osaka (JP); Hiroaki MACHITANI, Osaka (JP); Teppei NIINO, Osaka (JP); Takahiro IKEDA, Osaka (JP)

(73) Assignee: NITTO DENKO CORPORATION, Osaka (JP)

(21) Appl. No.: 18/994,914

(22) PCT Filed: Jun. 26, 2023
(86) PCT No.: PCT/JP2023/023618

§ 371 Date: Jan. 15, 2025

(30) Foreign Application Priority Data
Jul. 21, 2022 (JP) 2022-116361
Apr. 27, 2023 (JP) 2023-073353

(51) Int. Cl. H05K 1/181; H05K 3/30

(52) U.S. Cl. CPC H05K 1/181; H05K 3/301; H05K 2201/09236; H05K 2201/09263; H05K 2201/10121; H05K 2201/10424

(57) ABSTRACT

A wiring circuit board includes a frame, a mounting portion, and a joint. The mounting portion is surrounded by the frame and is spaced apart from the frame. The joint connects the frame to the mounting portion. Each of the frame and the mounting portion includes a base insulating layer, a wiring layer, and a cover insulating layer, and may include a metal supporting layer. The base insulating layer is disposed on one surface of the metal supporting layer in a thickness direction. The wiring layer is disposed on one surface of the base insulating layer in the thickness direction. The cover insulating layer is disposed on one surface of the base insulating layer in the thickness direction and covers a portion of the wiring layer. The joint does not include the metal supporting layer. The joint includes the base insulating layer, the wiring layer, and the cover insulating layer.

### TECHNICAL FIELD

The present invention relates to a wiring circuit board.

### BACKGROUND ART

A wiring circuit board for mounting an imaging element is known (ref: for example, Patent Document 1 below). The wiring circuit board described in Patent Document 1 includes a frame, a mounting portion surrounded by the frame, and a supporting member which connects them. The supporting member is made of a rigid material. The rigid material includes stainless steel. The wiring circuit board described in Patent Document 1 is provided in an imaging device in a state of mounting the imaging element in the mounting portion. In the wiring circuit board described in Patent Document 1, the frame elastically supports the mounting portion by the supporting member.

When the imaging device moves (vibrates), the frame moves (vibrates). Then, the mounting portion swings (sways) interlocked with the movement (vibration) of the frame. However, the above-described swing (sway) of the mounting portion is corrected by the supporting member. The above-described correction is referred to as a swing correction (sway correction).

### CITATION LIST

### Patent Document

Patent Document 1: Japanese Unexamined Patent Application Publication No. 2020-30306

### SUMMARY OF THE INVENTION

### Problem to be Solved by the Invention

There is a demand that a swing of the mounting portion is corrected with small force in accordance with the application and purpose of the wiring circuit board. However, in the wiring circuit board described in Patent Document 1, there is a problem that the above-described demand cannot be satisfied.

The present invention provides a wiring circuit board capable of correcting a swing of a mounting portion with small force.

### Means for Solving the Problem

The present invention [1] includes a wiring circuit board including a frame, a mounting portion surrounded by the frame and being spaced apart from the frame, and a joint connecting the frame to the mounting portion, wherein each of the frame and the mounting portion includes a base insulating layer, a wiring layer disposed on one surface of the base insulating layer in a thickness direction, and a cover insulating layer disposed on one surface of the base insulating layer in the thickness direction and covering a portion of the wiring layer, and may include a metal supporting layer disposed on the other surface of the base insulating layer in the thickness direction; and the joint does not include the metal supporting layer, and includes the base insulating layer, the wiring layer, and the cover insulating layer.

In the wiring circuit board, the joint does not include the metal supporting layer. Therefore, the rigidity of the joint is reduced. As a result, it is possible to correct a swing of the mounting portion with small force.

The present invention [2] includes the wiring circuit board described in [1], wherein the wiring layer in the mounting portion includes a plurality of terminals spaced apart from each other, and a plurality of wirings spaced apart from each other and electrically connected to the plurality of terminals; the joint includes a plurality of joint wirings spaced apart from each other and electrically connected to the plurality of wirings; the mounting portion has a first portion in which the plurality of wirings extend from the plurality of terminals, and a second portion disposed between the first portion and an outer peripheral edge of the mounting portion and in which the plurality of wirings converge; and the joint is connected to the second portion.

In the wiring circuit board, the joint is connected to the second portion in which the wirings converge. Therefore, in the joint, it is possible to suppress the spread of the connecting portion connected to the second portion. As a result, it is possible to reliably reduce the rigidity of the joint.

Further, in a case where the frame is moved and the joint is flexed, when the connecting portion is spread, a difference between the force applied to a central portion in a width direction in the joint, and the force applied to one end portion in the width direction is increased, and therefore, the swing of the mounting portion may not be accurately controlled.

However, in the wiring circuit board, in a case where the frame is moved and the joint is flexed, since the spread of the connecting portion is suppressed, the difference between the force applied to the central portion in the width direction in the joint, and the force applied to one end portion in the width direction is reduced, and therefore, it is possible to accurately control the swing of the mounting portion.

The present invention [3] includes the wiring circuit board described in [1] or [2], wherein the mounting portion has a side at an outer peripheral edge of the mounting portion, the joint includes a connecting portion to which the joint is connected at the side, and a ratio (length of the connecting portion/length of the side) of a length of the connecting portion in a direction along the side to the length of the side is 0.3 or less.

In the wiring circuit board, since the ratio of the length of the connecting portion in the direction along the side to the length of the side is 0.3 or less, the spread of the connecting portion is suppressed. Therefore, it is possible to reliably reduce the rigidity of the joint.

Further, in a case where the frame is moved and the joint is flexed, when the connecting portion is spread, the difference between the force applied to the central portion in the width direction in the joint, and the force applied to one end portion in the width direction is increased, and therefore, the swing of the mounting portion may not be accurately controlled.

However, in the wiring circuit board, in a case where the frame is moved and the joint is flexed, since the spread of the connecting portion is suppressed, the difference between the force applied to the central portion in the width direction in the joint, and the force applied to one end portion in the width direction is reduced, and therefore, it is possible to accurately control the swing of the mounting portion.

The present invention [4] includes the wiring circuit board described in any one of [1] to [3], wherein the mounting portion has the side at the outer peripheral edge of the mounting portion; and the joint is connected to a central region including a central portion at the side, and having a length of a half of the length of the side.

In the wiring circuit board, since the joint is connected to the central region, it is possible to accurately control the swing of the mounting portion.

The present invention [5] includes the wiring circuit board described in [3], wherein the joint is connected to a central region including a central portion at the side, and having a length of a half of the length of the side.

In the wiring circuit board, since the joint is connected to the central region, it is possible to accurately control the swing of the mounting portion.

The present invention [6] includes the wiring circuit board described in [4] or [5], wherein the joint is connected to the central portion of the side.

In the wiring circuit board, since the joint is connected to the central portion, it is possible to accurately control the swing of the mounting portion.

The present invention [7] includes the wiring circuit board described in any one of [1] to [6], wherein the mounting portion has a plurality of sides at the outer peripheral edge of the mounting portion, the plurality of joints are provided corresponding to the plurality of sides, and of the plurality of joints, a difference in length between the longest joint and the shortest joint is 3 mm or less.

In the wiring circuit board, since the difference in length between the longest joint and the shortest joint is 3 mm or less, it is possible to improve the accuracy of the swing correction of the mounting portion.

The present invention [8] includes the wiring circuit board described in any one of [1] to [7], wherein the base insulating layer and the cover insulating layer in the joint have a slit disposed between the plurality of joint wirings.

In the wiring circuit board, since the base insulating layer and the cover insulating layer in the joint have the slit, it is possible to further reduce the rigidity of the joint.

The present invention [9] includes the wiring circuit board described in [8], wherein the slit extends along the plurality of joint wirings, and the joint has a sub-joint dividing the slit in a direction in which the slit extends and connecting the plurality of joint wirings.

In the wiring circuit board, it is possible to suppress an excessive reduction of the rigidity of the joint caused by the slit by the sub-joint. Therefore, it is possible to suppress an excessive deformation of the joint.

The present invention [10] includes the wiring circuit board described in [9], wherein the joint includes a plurality of wiring body portions divided by the slit, and the one wiring body portion includes at least two joint wirings.

In the wiring circuit board, since the one wiring body portion includes at least two wirings, at least the two wirings can function as differential wirings.

The present invention [11] includes the wiring circuit board described in [10], wherein the slit extends along the plurality of wiring body portions, and the joint has a sub-joint dividing the slit in a direction in which the slit extends and connecting the plurality of wiring body portions.

In the wiring circuit board, it is possible to suppress the excessive reduction of the rigidity of the joint caused by the slit by the sub-joint. Therefore, it is possible to suppress the excessive deformation of the joint.

The present invention [12] includes the wiring circuit board described in any one of [1] to [11], wherein the wiring layer in the joint includes a ground wiring electrically connected to the metal supporting layer.

The present invention [13] includes the wiring circuit board described in any one of [1] to [12], wherein the joint has a curved shape.

In the wiring circuit board, since the joint has the curved shape, it is possible to improve the accuracy of the swing correction as compared with an embodiment having a linear shape and/or a bent shape

The present invention [14] includes the wiring circuit board described in [1] or [2], wherein the mounting portion has a generally rectangular shape, and has a side at the outer peripheral edge of the mounting portion; the frame has a generally rectangular frame shape, and has a facing side facing the side and a non-facing side adjacent to the facing side and not facing the side; and the joint connects the side to the non-facing side.

In the wiring circuit board, since the joint connects the side to the non-facing side which does not face the side, it is possible to make the joint longer. Therefore, the rigidity of the joint is reduced.

The present invention [15] includes the wiring circuit board described in [3], wherein the mounting portion has a generally rectangular shape; the frame has a generally rectangular frame shape, and has a facing side facing the side and a non-facing side adjacent to the facing side and not facing the side; and the joint connects the side to the non-facing side.

### Effect of the Invention

A wiring circuit board of the present invention can correct a swing of a mounting portion with small force.

### BRIEF DESCRIPTION OF THE DRAWINGS

FIG. 1 shows a plan view of one embodiment of a wiring circuit board of the present invention.

FIG. 2 shows an enlarged view of the wiring circuit board shown in FIG. 1.

FIG. 3 shows a cross-sectional view along an A-A line in FIG. 2.

FIG. 4 shows production process views of the wiring circuit board shown in FIG. 3:

FIG. 4A illustrating a step of forming a base insulating layer,

FIG. 4B illustrating a step of forming a wiring layer,

FIG. 4C illustrating a step of forming a cover insulating layer,

FIG. 4D illustrating a step of forming a metal supporting layer, and

FIG. 4E illustrating a step of mounting an imaging element and an external board on the wiring circuit board.

FIG. 5 shows a plan view of a first modified example.

FIG. 6 shows a plan view of a second modified example.

FIG. 7 shows a plan view of a third modified example.

FIG. 8 shows a plan view of a fourth modified example.

FIG. 9 shows a cross-sectional view along an A-A line in FIG. 8.

FIG. 10 shows a cross-sectional view of a fifth modified example.

FIG. 11 shows a cross-sectional view of a sixth modified example.

### DESCRIPTION OF EMBODIMENTS

### 1. One Embodiment of Wiring Circuit Board

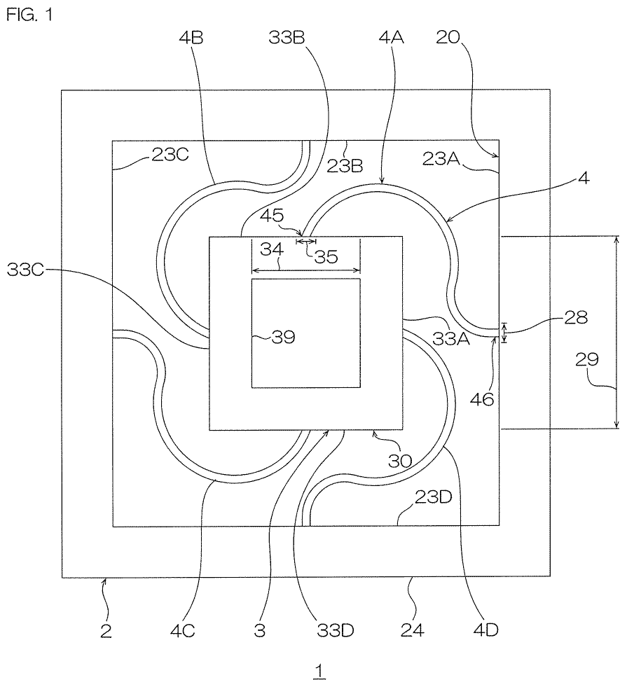

One embodiment of a wiring circuit board of the present invention is described with reference to FIGS. 1 to 3.

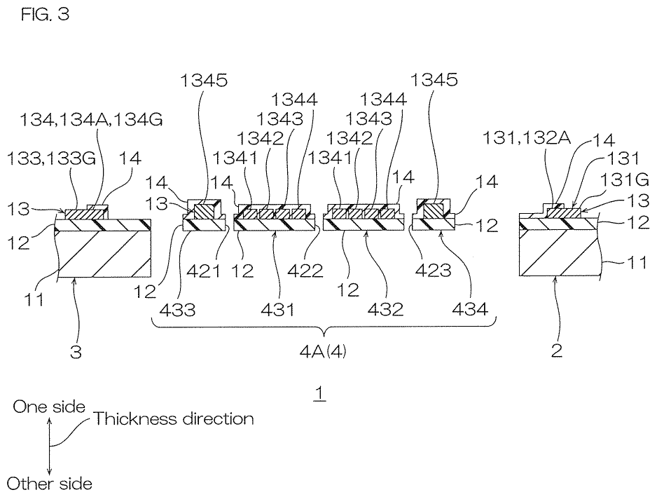

As shown in FIG. 1, a wiring circuit board 1 has a sheet shape. As shown in FIG. 3, the wiring circuit board 1 has a thickness. As shown in FIG. 1, the wiring circuit board 1 extends in a plane direction. The plane direction is orthogonal to a thickness direction. The wiring circuit board 1 includes a frame 2, a mounting portion 3, and a joint 4.

### 1.2 Frame 2

In the present embodiment, the frame 2 has a generally rectangular frame shape. The frame includes an inner peripheral edge 20. In the present embodiment, the frame 2 has four sides 23A. 23B, 23C, and 23D at the inner peripheral edge 20. The four sides 23A, 23B, 23C, and 23D are disposed in order counterclockwise when viewed from the top. The side 23A and the side 23C face each other. The side 23B connects one end portion of the side 23A to one end portion of the side 23C. The side 23D connects the other end portion of the side 23A to the other end portion of the side 23C. The side 23B and the side 23D face each other.

As shown in FIG. 3, the frame 2 includes a metal supporting layer 11, a base insulating layer 12, a wiring layer 13, and a cover insulating layer 14.

### 1.2.1 Metal Supporting Layer 11 in Frame 2

In the frame 2, the metal supporting layer 11 extends in the plane direction. The metal supporting layer 11 forms the other surface of the frame 2 in the thickness direction.

Examples of a material for the metal supporting layer 11 in the frame 2 include rigid materials. Examples of the rigid material include stainless steel, 42-alloy, aluminum, copper-beryllium, phosphor bronze, copper, silver, nickel, chromium, titanium, tantalum, platinum, gold, and copper alloys. As the rigid material, from the viewpoint of ensuring the strength of the frame 2 and the mounting portion 3, preferably, stainless steel and copper alloys are used. A thickness of the metal supporting layer 11 in the frame 2 is, for example, 30 μm or more, preferably 100 μm or more, and for example, 10,000 μm or less, preferably 1,000 μm or less.

### 1.2.2 Base Insulating Layer 12 in Frame 2

In the frame 2, the base insulating layer 12 is disposed on one surface of the metal supporting layer 11 in the thickness direction. In other words, in the frame 2, the metal supporting layer 11 is disposed on the other surface of the base insulating layer 12 in the thickness direction. The base insulating layer 12 is in contact with one surface of the metal supporting layer 11.

Examples of the material for the base insulating layer 12 in the frame 2 include resins, and preferably, a polyimide resin is used. The thickness of the base insulating layer 12 in the frame 2 is, for example, 1 μm or more, preferably 5 μm or more, and for example, below 20 μm, preferably 15 μm or less.

### 1.2.3 Wiring Layer 13 in Frame 2

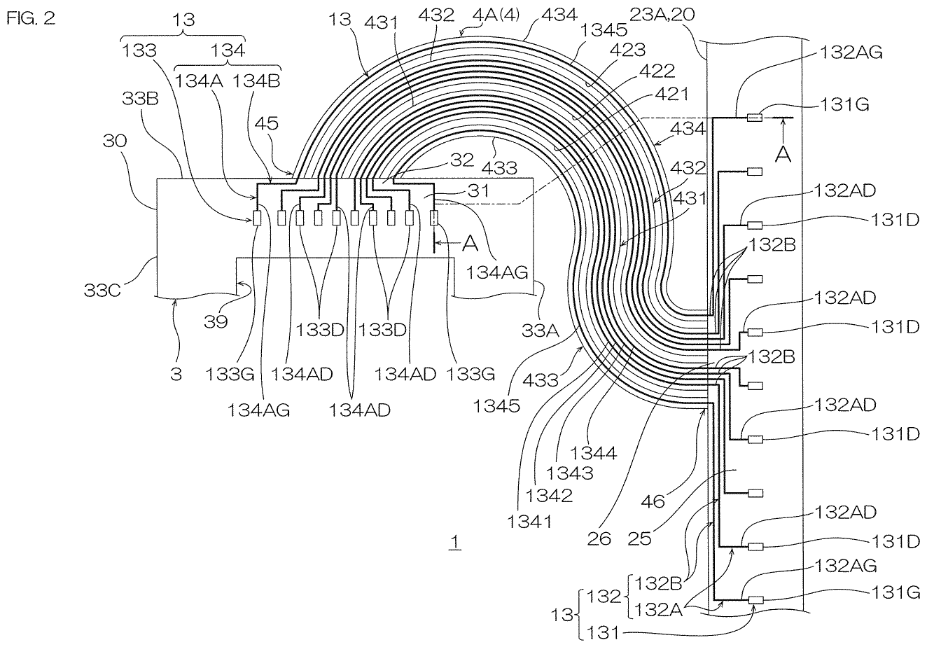

In the frame 2, the wiring layer 13 is disposed on one surface of the base insulating layer 12 in the thickness direction. The wiring layer 13 is in contact with one surface of the base insulating layer 12. As shown in FIG. 2, the wiring layer 13 includes a plurality of frame terminals 131 and a plurality of frame wirings 132.

### 1.2.3.1 Frame Terminal 131

The plurality of frame terminals 131 are provided corresponding to each of the four sides 23A, 23B (ref: FIGS. 1), 23C (ref: FIG. 1), and 23D (ref: FIG. 1). The plurality of frame terminals 131 corresponding to the side 23A are spaced apart from each other along the side 23A. Preferably, the plurality of frame terminals 131 are equally spaced apart from each other along the side 23A. The plurality of frame terminals 131 corresponding to the side 23A include a plurality of frame ground terminals 131G and a plurality of frame differential terminals 131D. Although not shown, the plurality of frame terminals 131 corresponding to each of the sides 23B (ref: FIGS. 1), 23C (ref: FIG. 1), and 23D (ref: FIG. 1) have the same configuration as the plurality of frame terminals 131 corresponding to the side 23A.

### 1.2.3.2 Frame Wiring 132

The plurality of frame wirings 132 are electrically connected to the plurality of frame terminals 131. In the present embodiment, the plurality of frame wirings 132 corresponding to the side 23A extend from each of the plurality of frame terminals 131 corresponding to the side 23A, bend, and converge to each other to thereafter reach the inner peripheral edge 20. Specifically, each of the plurality of frame wirings 132 includes a frame extending line 132A and a frame converging line 132B.

The frame extending line 132A corresponding to the side 23A extends from each of the plurality of frame terminals 131 corresponding to the side 23A toward the side 23A. The plurality of frame extending lines 132A corresponding to the side 23A are provided corresponding to the plurality of frame terminals 131 corresponding to the side 23A.

The plurality of frame extending lines 132A are spaced apart from each other in a direction along the side 23A. Each of the plurality of frame extending lines 132A extends in the direction intersecting the side 23A. The frame extending line 132A includes a plurality of frame ground extending lines 132AG and a plurality of frame differential extending lines 132AD. Each of the plurality of frame ground extending lines 132AG extends from each of the plurality of frame ground terminals 131G. Each of the plurality of frame differential extending lines 132AD extends from each of the plurality of frame differential terminals 131D.

In the frame 2, a region where the plurality of frame extending lines 132A are provided is referred to as a third portion 25.

The frame extending line 132A corresponding to each of the sides 23B (ref: FIGS. 1), 23C (ref: FIG. 1), and 23D (ref: FIG. 1) has the same configuration as the frame extending line 132A corresponding to the side 23A described above.

The plurality of frame converging lines 132B corresponding to the side 23A are provided corresponding to the plurality of frame extending lines 132A corresponding to the side 23A. The plurality of frame converging lines 132B converge to each other, and go toward the vicinity of a second connecting portion 46 (described later) of a joint 4A in the frame 3. Each of the plurality of frame converging lines 132B starts from one end edges of the plurality of frame extending lines 132A, and finishes at a site which is overlapped with the side 23A in the thickness direction. One end edge is an end edge at the opposite side of the frame terminal 131 in the frame extending line 132A. The starting point of the frame converging line 132B is a first bending point in the frame wiring 132. The frame converging line 132B is bent in a region facing the second connecting portion 46 of the joint 4A. The above-described bending in the frame converging line 132B is a second bending point in the frame wiring 132. The second bending point of the frame wiring 132 is spaced apart from the first bending point of the frame wiring 132 in the direction along the side 23A. The second bending point may not face the corresponding frame terminal 131, while facing the joint 4A in the direction orthogonal to the side 23A. The wiring density of the plurality of frame converging lines 132B is higher than the wiring density of the frame extending line 132A described above. The plurality of frame converging lines 132B may have equally spaced portions spaced apart from each other. In the present embodiment, each of the plurality of frame converging lines 132B has a generally L-shape.

In the frame 2, the region where the frame converging line 132B is provided is referred to as a fourth portion 26. The fourth portion 26 is disposed between an inner peripheral edge 20 (the side 23A) and the above-described third portion 25. The side 23A, the fourth portion 26, and the third portion 25 are disposed in order. The wiring density of the frame converging line 132B in the fourth portion 26 is higher than the wiring density of the frame extending line 132A in the third portion 25.

The frame converging line 132B corresponding to each of the sides 23B (ref: FIGS. 1), 23C (ref: FIG. 1), and 23D (ref: FIG. 1) has the same configuration as the frame converging line 132B corresponding to the side 23A described above.

Examples of the material for the wiring layer 13 in the frame 2 include conductors. As the conductor, preferably, copper is used.

The thickness of the wiring layer 13 in the frame 2 is, for example, 1 μm or more, preferably 5 μm or more, and for example, 50 μm or less, preferably 35 μm or less.

### 1.2.4 Cover Insulating Layer 14 in Frame 2

As shown in FIG. 3, in the frame 2, the cover insulating layer 14 is disposed on one surface of the base insulating layer 12 in the thickness direction. The cover insulating layer 14 covers the frame wiring 132 (ref: FIG. 2, the frame extending line 132A and the frame converging line 132B) as a portion of the wiring layer 13. The cover insulating layer 14 exposes the frame terminal 131 (ref: FIG. 2, the frame ground terminal 131G and the frame differential terminal 131D) as a remaining portion of the wiring layer 13.

Examples of the material for the cover insulating layer 14 include resins, and preferably, a polyimide resin is used. The thickness of the cover insulating layer 14 in the frame 2 is, for example, 1 μm or more, preferably 5 μm or more, and for example, below 20 μm, preferably 15 μm or less.

### 1.2.5 Dimension of Frame 2

An external dimension of the frame 2 is not limited. As shown in FIG. 1, each of an interval between the side 23A and the side 23C, and the interval between the side 23B and the side 23D is, for example, 5 mm or more, preferably 8 mm or more, and for example, 50 mm or less, preferably 30 mm or less. A length of each of the sides 23A, 23B, 23C, and 23D is, for example, 5 mm or more, preferably 8 mm or more, and for example, 50 mm or less, preferably 30 mm or less. A width of the frame 2 is, for example, 0.1 mm or more, preferably 0.3 mm or more, and for example, 50 mm or less, preferably 30 mm or less. The width of the frame 2 is the length between the inner peripheral edge 20 and the outer peripheral edge.

As shown in FIG. 2, the width of each of the plurality of frame terminals 131 is, for example, 10 μm or more, preferably 30 μm or more, and for example, 3000 μm or less, preferably 1000 μm or less.

A pitch of the plurality of frame terminals 131 is, for example, 30 μm or more, preferably 50 μm or more, and for example, 2000 μm or less, preferably 1000 μm or less. The pitch is the interval of each of the end edges of the frame terminals 131 adjacent to each other. Each of the two end edges is one end edge in the direction along the side 23A. The definition of the pitch is hereinafter the same.

In contrast, in the present embodiment, the pitch at the equally spaced portions of the plurality of frame converging lines 132B is smaller than the pitch of the plurality of frame extending lines 132A. The pitch at the equally spaced portions of the plurality of frame converging lines 132B is, for example, 1500 μm or less, preferably 1000 μm or less, more preferably 800 μm or less, and for example, 10 μm or more. A ratio of the pitch of the equally spaced portions of the plurality of frame converging lines 132B to the pitch of the plurality of frame extending lines 132A is, for example, below 1, preferably 0.8 or less, more preferably 0.5 or less, and for example, 0.01 or more.

The width of the frame wiring 132 is, for example, 1 μm or more, preferably 5 μm or more, and for example, 3000 μm or less, preferably 1000 μm or less.

### 1.3 Mounting Portion 3

As shown in FIG. 1, the mounting portion 3 is surrounded by the frame 2. The mounting portion 3 is spaced apart from the frame 2. In the present embodiment, the mounting portion 3 has a generally rectangular shape. Preferably, the mounting portion 3 has a generally rectangular outer shape, and specifically, has a generally rectangular frame shape. The mounting portion 3 includes an outer peripheral edge 30 and an inner peripheral edge 39. In the present embodiment, the mounting portion 3 includes four sides 33A, 33B, 33C, and 33D at the outer peripheral edge 30.

The four sides 33A, 33B, 33C, and 33D are disposed in order counterclockwise when viewed from the top. Each of the sides 33A, 33B, 33C, and 33D of the mounting portion 3 faces each of the sides 23A, 23B, 23C, and 23D of the frame 2.

In other words, the side 33B of the mounting portion 3 faces (is opposed to) the side 23B of the frame 2. In other words, the side 23B is a facing side with respect to the side 33B. The side 33B extends in the same direction as the side 23B.

The side 33B of the mounting portion 3 does not face (is not opposed to) the side 23A of the frame 2. In other words, the side 23A is a non-facing side with respect to the side 33B. The side 33B is adjacent to the side 33A. The side 33B extends in the direction intersecting the side 23A. Preferably, the side 33B extends in the direction orthogonal to the side 23A.

The side 33C is along the same direction as the side 33A. The side 33B connects one end portion of the side 33A to one end portion of the side 33C. The side 33D connects the other end portion of the side 33A to the other end portion of the side 33C. The side 33D is along the same direction as the side 33B.

As shown in FIG. 3, the mounting portion 3 includes the metal supporting layer 11, the base insulating layer 12, the wiring layer 13, and the cover insulating layer 14.

### 1.3.1 Metal Supporting Layer 11 in Mounting Portion 3

In the mounting portion 3, the metal supporting layer 11 extends in the plane direction. The metal supporting layer 11 forms the other surface of the mounting portion 3 in the thickness direction. Each of the material and the thickness of the metal supporting layer 11 in the mounting portion 3 is the same as each of the material and the thickness of the metal supporting layer 11 in the frame 2.

### 1.3.2 Base Insulating Layer 12 in Mounting Portion 3

In the mounting portion 3, the base insulating layer 12 is disposed on one surface of the metal supporting layer 11 in the thickness direction. In other words, in the mounting portion 3, the metal supporting layer 11 is disposed on the other surface of the base insulating layer 12 in the thickness direction. The base insulating layer 12 is in contact with one surface of the metal supporting layer 11. Each of the material and the thickness of the base insulating layer 12 in the mounting portion 3 is the same as each of the material and the thickness of the base insulating layer 12 in the frame 2.

### 1.3.3 Wiring Layer 13 in Mounting Portion 3

In the mounting portion 3, the wiring layer 13 is disposed on one surface of the base insulating layer 12 in the thickness direction. The wiring layer 13 is in contact with one surface of the base insulating layer 12. As shown in FIG. 2, the wiring layer 13 in the mounting portion 3 includes a plurality of terminals 133 and a plurality of wirings 134.

### 1.3.3.1 Terminal 133

The plurality of terminals 133 are provided corresponding to each of the four sides 33A (ref: FIGS. 1), 33B, 33C (ref: FIG. 1), and 33D (ref: FIG. 1). Specifically, the plurality of terminals 133 corresponding to the side 33B are spaced apart from each other in the direction along the side 33B. Preferably, the plurality of terminals 133 are equally spaced apart from each other in the direction along the side 33B. The plurality of terminals 133 corresponding to the side 33B include a plurality of ground terminals 133G and a plurality of differential terminals 133D. Although not shown, a plurality of terminals corresponding to each of the sides 33A (ref: FIGS. 1), 33C (ref: FIG. 1), and 33D (ref: FIG. 1) have the same configuration as the terminal 133 corresponding to the side 33B.

### 1.3.3.2 Wiring 134

The plurality of wirings 134 are electrically connected to the plurality of terminals 133. The plurality of wirings 134 are spaced apart from each other. In the present embodiment, the plurality of wirings 134 corresponding to the side 33B extend from each of the plurality of terminals 133 corresponding to the side 33B, and then, converge to each other to thereafter reach the outer peripheral edge 30. Specifically, each of the plurality of wirings 134 includes an extending line 134A and a converging line 134B.

The extending line 134A corresponding to the side 33B extends from each of the plurality of terminals 133 corresponding to the side 33B toward the side 33B. The plurality of extending lines 134A corresponding to the side 33B are provided corresponding to the plurality of terminals 133 corresponding to the side 33B.

The plurality of extending lines 134A are spaced apart from each other in the direction along the side 33B. Each of the plurality of extending lines 134A extends in the direction intersecting the side 33B. The extending line 134A includes a plurality of ground extending lines 134AG and a plurality of differential extending lines 134AD. Each of the plurality of ground extending lines 134AG extends from each of the plurality of ground terminals 133G. Each of the plurality of differential extending lines 134AD extends from each of the plurality of differential terminals 133D.

In the mounting portion 3, a region where the plurality of extending lines 134A are provided is referred to as a first portion 31. In other words, the mounting portion 3 includes the first portion 31. In other words, in the first portion 31, the plurality of wirings 134 extend from the plurality of terminals 133.

The extending line 134A corresponding to each of the sides 33A (ref. FIGS. 1), 33C (ref. FIG. 1), and 33D (ref: FIG. 1) has the same configuration as the extending line 134A corresponding to the above-described side 33B.

The plurality of converging lines 134B corresponding to the side 33B are provided corresponding to the extending line 134A corresponding to the side 33B. The plurality of converging lines 134B converge to each other, and go toward the vicinity of a connecting portion 45 (described later) of the joint 4A in the mounting portion 3. Each of the plurality of converging lines 134B starts from one end edges of the plurality of extending lines 134A, and finishes at the site which is overlapped with the side 33B in the thickness direction. One end edge is the end edge at the opposite side of the terminal 133 in the extending line 134A. The starting point of the converging line 134B is the first bending point in the wiring 134. The converging line 134B is bent in a region facing the connecting portion 45 of the joint 4A. The above-described bending in the converging line 134B is the second bending point in the wiring 134. The second bending point of the wiring 134 is spaced apart from the first bending point of the wiring 134 in the direction along the side 33B. The second bending point may not face the corresponding terminal 133, while facing the joint 4A in the direction orthogonal to the side 33B. The wiring density of the plurality of converging lines 134B is higher than the wiring density of the extending line 134A described above. The plurality of converging lines 134B may have the equally spaced portions spaced apart from each other. In the present embodiment, each of the plurality of converging lines 134B has a generally L-shape.

In the mounting portion 3, the region where the converging line 134B is provided is referred to as a second portion 32. In other words, the mounting portion 3 has the second portion 32. The second portion 32 is disposed between the outer peripheral edge 30 (the side 33A) and the above-described first portion 31. The side 33A, the first portion 31, and the second portion 32 are disposed in order toward the inner peripheral edge 39. In the second portion 32, the plurality of wirings 134 converge. The wiring density of the converging line 134B in the second portion 32 is higher than the wiring density of the extending line 134A in the first portion 31.

### 1.3.4 Cover Insulating Layer 14 in Mounting Portion 3

As shown in FIG. 3, in the mounting portion 3, the cover insulating layer 14 is disposed on one surface of the base insulating layer 12 in the thickness direction. The cover insulating layer 14 covers the wiring 134 (ref: FIG. 2, the extending line 134A and the converging line 134B) as a portion of the wiring layer 13. The cover insulating layer 14 exposes the terminal 133 as the remaining portion of the wiring layer 13 (ref: FIG. 2).

### 1.3.5 Dimension of Mounting Portion 3

The external dimension of the mounting portion 3 is not limited. As shown in FIG. 1, each of the interval between the side 33A and the side 33C, and the interval between the side 33B and the side 33D is, for example, 3 mm or more, preferably 5 mm or more, and for example, 50 mm or less, preferably 30 mm or less. The length of each of the sides 33A, 33B, 33C, and 33D is, for example, 3 mm or more, preferably 5 mm or more, and for example, 50 mm or less, preferably 30 mm or less.

The width of the mounting portion 3 is, for example, 0.3 mm or more, preferably 0.5 mm or more, and for example, 30 mm or less, preferably 20 mm or less. The width of the mounting portion 3 is the length between the outer peripheral edge 30 and the inner peripheral edge 39.

As shown in FIG. 2, the width of each of the plurality of terminals 133 is the same as the width of each of the plurality of frame terminals 131 described above.

The pitch of the plurality of terminals 133 is, for example, 30 μm or more, preferably 50 μm or more, and for example, 2000 μm or less, preferably 1000 μm or less. The interval between the terminals 133 adjacent to each other is, for example, 10 μm or more, preferably 30 μm or more, more preferably 1500 μm or more, and for example, 800 μm or less.

The pitch of the plurality of extending lines 134A is preferably the same as the pitch of the plurality of terminals 133. The pitch at the equally spaced portion of the converging line 134B is smaller than the pitch of the plurality of extending lines 134A. The pitch at the equally spaced portion of the converging line 134B is, for example, 1500 μm or less, preferably 1000 μm or less, more preferably 800 μm or less, and for example, 10 μm or more. The ratio of the pitch of the equally spaced portion of the converging line 134B to the pitch of the plurality of extending lines 134A is, for example, below 1, preferably 0.8 or less, more preferably 0.5 or less, and for example, 0.01 or more.

The width of the wiring 134 is the same as the width of the above-described frame wiring 132.

### 1.4 Joint 4

As shown in FIG. 1, the joint 4 is disposed between the frame 2 and the mounting portion 3. The joint 4 connects the frame 2 to the mounting portion 3. The plurality of joints 4 are provided corresponding to the plurality of sides 33 in the mounting portion 3. In the present embodiment, each of the plurality of joints 4A, 4B, 4C, and 4D corresponds to each of the plurality of sides 33B, 33C, 33D, and 33A in the mounting portion 3. Specifically, the joint 4A connects the side 23A in the frame 2 to the side 33B in the mounting portion 3. The joint 4B connects the side 23B in the frame 2 to the side 33C in the mounting portion 3. The joint 4C connects the side 23C in the frame 2 to the side 33D in the mounting portion 3. The joint 4D connects the side 23D in the frame 2 to the side 33A in the mounting portion 3.

In the following, detailed descriptions of the joint 4A are provided. The joints 4B, 4C, and 4D have the same configuration as the joint 4A, and the detailed descriptions of these are omitted.

### 1.4.1 Shape of Joint 4a

As shown in FIG. 2, in the present embodiment, the joint 4A has a curved shape when viewed from the top. Preferably, the joint 4A has only the curved shape without having a linear shape and/or a bent shape. Specifically, the joint 4A has an S-shape or a hooked shape. When the joint 4A has the curved shape, since the stress can be evenly relaxed without being locally concentrated, it is possible to improve the accuracy of a swing correction of the mounting portion 3.

### 1.4.2 Connection of Joint 4 to Mounting Portion 3

The joint 4A is connected to the second portion 32 in the mounting portion 3. That is, in the mounting portion 3, the joint 4A is not connected to the first portion 31 where the plurality of extending lines 134A having the same pitch (relatively large pitch) as the plurality of terminals 133 are disposed, and is connected to the second portion 32 where the plurality of converging lines 134B having the smaller pitch than the plurality of terminals 133 are disposed.

The joint 4A includes the connecting portion 45 connected to the second portion 32 described above. As shown in FIG. 1, for example, the connecting portion 45 is connected to a central region 34 of the side 33B in the mounting portion 3.

The central region 34 is a region including a central portion 35 in the side 33B. The central portion 35 is a central point in the side 33B and the vicinity thereof. The central region 34 has a length of a half of the length of the side 33B. The central region 34 preferably has the length of one third of the length of the side 33B, and more preferably has the length of one fourth of the length of the side 33B.

Preferably, the joint 4A is connected to the central portion 35 of the side 33B.

The ratio (length of the connecting portion 45/length of the side 33B) of the length of the connecting portion 45 in the direction along the side 33B to the length of the side 33B is, for example, 0.3 or less, preferably 0.25 or less, more preferably 0.2 or less, and for example, 0.01 or more.

When the ratio of the length of the connecting portion 45 in the direction along the side 33B to the length of the side 33B is the above-described upper limit or less, it is possible to suppress the spread of the connecting portion 45 in the direction in which the side 33B extends. Therefore, it is possible to reliably reduce the rigidity of the joint 4A.

### 1.4.3 Connection of Joint 4 to Frame 2

As shown in FIG. 2, the joint 4A is connected to the fourth portion 26 in the frame 2. That is, in the frame 2, the joint 4A is not connected to the third portion 25 where the plurality of frame extending lines 132A having the same pitch (relatively large pitch) as the plurality of frame terminals 131 are disposed, and is connected to the fourth portion 26 where the plurality of converging lines 134B having the smaller pitch than the plurality of frame terminals 131 are disposed.

The joint 4A includes the second connecting portion 46 connected to the fourth portion 26. As shown in FIG. 1, for example, the second connecting portion 46 is connected to a second central region 29 of the side 23A in the frame 2.

The second central region 29 is a region including a second central portion 28 in the side 23A. The second central portion 28 is the central point in the side 23A and the vicinity thereof. The second central region 29 has the length of a half of the length of the side 23A. The second central region 29 preferably has the length of one third of the length of the side 23A, and more preferably has the length of one fourth of the length of the side 23A.

Preferably, the joint 4A is connected to the second central portion 28 of the side 23A.

The ratio (length of the second connecting portion 46/length of the side 23A) of the length of the second connecting portion 46 in the direction along the side 23A to the length of the side 23A is, for example, 0.3 or less, preferably 0.25 or less, more preferably 0.2 or less, and for example, 0.01 or more.

When the ratio of the length of the second connecting portion 46 in the direction along the side 23A to the length of the side 23A is the above-described upper limit or less, it is possible to suppress the spread of the second connecting portion 46 in the direction in which the side 23A extends. Therefore, it is possible to reliably reduce the rigidity of the joint 4A.

As shown in FIG. 2, in the present embodiment, the joint 4A includes a plurality of slits 421, 422, and 423, a plurality of wiring body portions 431 and 432, and ground wiring body portions 433 and 434.

### 1.4.4 Slits 421, 422, 423

Each of the plurality of slits 421, 422, and 423 is disposed in an intermediate portion of the joint 4 in the direction intersecting the direction in which the joint 4 extends (intersecting direction, preferably, orthogonal direction). The plurality of slits 421, 422, and 423 are spaced apart from each other in the intersecting direction.

Each of the plurality of slits 421, 422, and 423 is disposed in the entire direction in which the joint 4 extends in the joint 4. The plurality of slits 421, 422, and 423 are disposed in order toward the intersecting direction. The plurality of slits 421, 422, and 423 partition the wiring body portion 431, the wiring body portion 432, the ground wiring body portion 433, and the ground wiring body portion 434. As shown in FIG. 3, each of the plurality of slits 421, 422, and 423 penetrates the base insulating layer 12 and the cover insulating layer 14 to be described later in the thickness direction.

### 1.4.5 Wiring Body Portions 431, 432

The wiring body portion 431 and the wiring body portion 432 are partitioned by the slits 421, 422, and 423. The wiring body portion 431 and the wiring body portion 432 are spaced apart from each other in the intersecting direction. The plurality of slits 421, 422, and 423 extend along the wiring body portions 431 and 432. Each of the wiring body portion 431 and the wiring body portion 432 includes four joint wirings 1341, 1342, 1343, and 1344, the base insulating layer 12, and the cover insulating layer 14.

The joint wirings 1341, 1342, 1343, and 1344 are spaced apart from each other in the intersecting direction. The joint wirings 1341, 1342, 1343, and 1344 are disposed in order in the intersecting direction. The plurality of slits 421, 422, and 423 extend along the joint wirings 1341, 1342, 1343, and 1344. In the present embodiment, the joint wirings 1341, 1342, 1343, and 1344 can function as differential wirings. For example, the joint wiring 1341 and the joint wiring 1342 operate as differential pairs. The joint wiring 1343 and the joint wiring 1344 operate as differential pairs.

The one base insulating layer 12 is in contact with the other surfaces of the joint wirings 1341, 1342, 1343, and 1344 in the thickness direction in each of the wiring body portions 431 and 432.

The one cover insulating layer 14 collectively covers the joint wirings 1341, 1342, 1343, and 1344 in each of the wiring body portions 431 and 432. The cover insulating layer 14 is in contact with one surface and an outer-side surface of each of the joint wirings 1341, 1342, 1343, and 1344.

### 1.4.6 Ground Wiring Body Portions 433, 434

The ground wiring body portion 433 is disposed apart from the wiring body portion 431 via the slit 421. The ground wiring body portion 434 is disposed apart from the wiring body portion 432 via the slit 423. Each of the ground wiring body portions 433 and 434 includes the ground wiring 1345, the base insulating layer 12, and the cover insulating layer 14.

The one base insulating layer 12 is in contact with the lower surface of the ground wiring 1345 in the thickness direction in each of the ground wiring body portions 433 and 434. The ground wiring 1345 is thicker than the joint wirings 1341, 1342, 1343, and 1344.

The one cover insulating layer 14 covers the ground wiring 1345 in each of the ground wiring body portions 433 and 434. The cover insulating layer 14 is in contact with one surface in the thickness direction and the outer-side surface of the ground wiring 1345.

As shown in FIG. 2, the ground wiring 1345 is electrically connected to the frame ground terminal 131G in the frame 2. Specifically, the ground wiring 1345 is electrically connected to the metal supporting layer 11 in the frame 2 via the converging line 134B corresponding to the ground extending line 134AG, the ground extending line 134AG, and the frame ground terminal 131G. Thus, the ground wiring 1345 is grounded to the frame ground terminal 131G.

As shown in FIG. 3, in the present embodiment, the joint 4A does not include the metal supporting layer 11. The metal supporting layer 11 is a layer disposed on the other surface of the base insulating layer 12 in the thickness direction. Examples of the material for the metal supporting layer 11 include the above-described rigid materials,

The joint 4A includes the base insulating layer 12, the wiring layer 13, and the cover insulating layer 14. Preferably, the joint 4A includes only the base insulating layer 12, the wiring layer 13, and the cover insulating layer 14.

### 1.4.7 Base Insulating Layer 12 in Joint 4A

In the joint 4A, the base insulating layer 12 forms the other surface of the joint 4A in the thickness direction. The base insulating layer 12 is exposed toward the other side in the thickness direction.

The base insulating layer 12 has the plurality of slits 421, 422, and 423 described above. The plurality of slits 421, 422, and 423 are disposed between the wiring body portions 431 and 432, between the wiring body portion 431 and the ground wiring body portion 433, and between the wiring body portion 432 and the ground wiring body portion 434.

### 1.4.8 Wiring Layer 13 in Joint 4A

In the joint 4A, the wiring layer 13 includes the above-described joint wirings 1341, 1342, 1343, and 1344 and the above-described two ground wirings 1345.

In the joint 4A, the wiring layer 13 is disposed on one surface of the base insulating layer 12 in the thickness direction. The wiring layer 13 is in contact with one surface of the base insulating layer 12. The joint wirings 1341, 1342, 1343, and 1344 are spaced apart from each other in the intersecting direction (preferably, orthogonal direction) in the joint 4A. As shown in FIG. 2, the joint wirings 1341, 1342, 1343, and 1344 are electrically connected to the plurality of wirings 134. Further, the joint wirings 1341, 1342, 1343, and 1344 are electrically connected to the plurality of frame wirings 132. That is, the plurality of joint wirings 1341, 1342, 1343, and 1344 electrically connect the plurality of frame wirings 132 in the frame 2 to the plurality of wirings 134 in the mounting portion 3.

### 1.4.9 Cover Insulating Layer 14 in Joint 4A

As shown in FIG. 3, in the joint 4A, the cover insulating layer 14 forms one surface of the joint 4A in the thickness direction. The cover insulating layer 14 is exposed toward one side in the thickness direction. The cover insulating layer 14 is disposed on one surface of the base insulating layer 12 in the thickness direction. The cover insulating layer 14 covers the plurality of joint wirings 1341, 1342, 1343, and 1344 and the ground wiring 1345.

The cover insulating layer 14 has the above-described plurality of slits 421, 422, and 423 together with the base insulating layer 12. Each of the plurality of slits 421, 422, and 423 penetrates the cover insulating layer 14 in the thickness direction. An inner-side surface partitioning each of the plurality of slits 421, 422, and 423 in the cover insulating layer 14 is flush with the inner-side surface partitioning each of the plurality of slits 421, 422, and 423 in the base insulating layer 12.

### 1.4.10 Dimension of Joint 4A

The ratio of the thickness of the ground wiring 1345 to the thickness of the joint wirings 1341, 1342, 1343, and 1344 is, for example, 0.5 or more, preferably 0.8 or more, more preferably 1 or more, and for example, 10 or less. The thickness of the joint wirings 1341, 1342, 1343, and 1344 is the same as the thickness of the frame wiring 132. The thickness of the ground wiring 1345 is, for example, 3 μm or more, preferably 6 μm or more, and for example, 100 μm or less, preferably 50 μm or less.

The plurality of joints 4A, 4B, 4C, and 4D may have the same lengths or may have the different lengths. When the lengths of the plurality of joints 4A, 4B, 4C, and 4D are different from each other, a difference in length between the longest joint 4 and the shortest joint 4 is, for example, 3 mm or less, preferably 2 mm or less, more preferably 1.5 mm or less. When the difference in length between the longest joint 4 and the shortest joint 4 is the above-descried upper limit or less, it is possible to improve the accuracy of the swing correction of the mounting portion 3.

The thickness of each of the plurality of wiring body portions 431 and 432 is, for example, 3 μm or more, preferably 5 μm or more, and for example, 100 μm or less, preferably 50 μm or less. The width of each of the plurality of wiring body portions 431 and 432 is, for example, 5 μm or more, preferably 10 μm or more, and for example, 500 μm or less, preferably 300 μm or less.

The thickness of each of the ground wiring body portions 433 and 434 is, for example, 3 μm or more, preferably 5 μm or more, and for example, 100 μm or less, preferably 50 μm or less. The width of each of the ground wiring body portions 433 and 434 is, for example, 5 μm or more, preferably 10 μm or more, and for example, 500 μm or less, preferably 300 μm or less.

The width of each of the slits 421, 422, and 423 is, for example, 5 μm or more, preferably 10 μm or more, and for example, 500 μm or less, preferably 300 μm or less.

### 1.5 Method for Producing Wiring Circuit Board 1

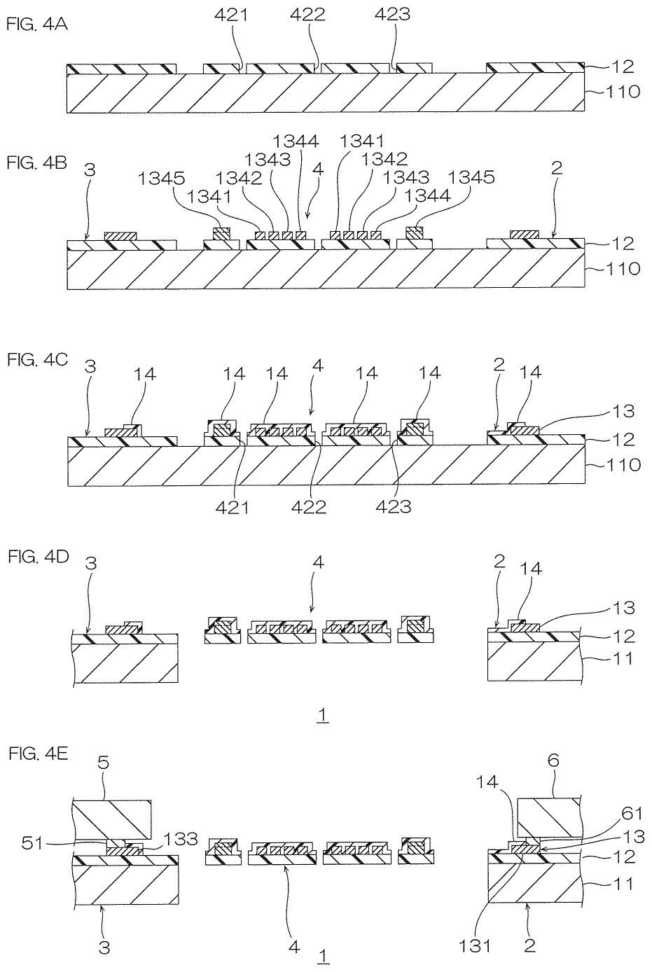

A method for producing the wiring circuit board 1 and mounting of an imaging element 5 are described with reference to FIGS. 4A to 4E.

As shown in FIG. 4A, in this method, first, the base insulating layer 12 is formed on one surface of a metal supporting board 110 in the thickness direction.

The metal supporting board 110 is a metal board for forming the metal supporting layer 11. The metal supporting board 110 is made of the same material as the metal supporting layer 11, and has the same thickness as the metal supporting layer 11.

For example, a resin is applied to one surface of the metal supporting board 110, and the base insulating layer 12 having a pattern corresponding to the frame 2, the mounting portion 3, and the joint 4 is formed by photolithography. In this step, the base insulating layer 12 of the frame 2, the base insulating layer 12 of the mounting portion 3, and the base insulating layer 12 of the joint 4 are formed simultaneously.

As shown in FIG. 4B, next, the wiring layer 13 is formed on one surface of the base insulating layer 12 in the thickness direction. For example, the wiring layer 13 is formed by a conductor pattern forming method. Examples of the conductor pattern forming method include additive methods and subtractive methods, and preferably, an additive method is used. In order to form the wiring layer 13 by the additive method, first, the wiring layer 13 of the frame 2, a portion of the wiring layer 13 of the mounting portion 3, and the wiring layer 13 of the joint 4 are formed simultaneously. A portion of the wiring layer 13 of the mounting portion 3 is other-side portions (ref: phantom line) of the joint wirings 1341, 1342, 1343, and 1344, and the ground wiring 1345 in the thickness direction. Thereafter, a one-side portion (ref: phantom line) of the ground wiring 1345 in the thickness direction is laminated on the other-side portion of the ground wiring 1345.

As shown in FIG. 4C, the cover insulating layer 14 is formed on one surface of the base insulating layer 12 in the thickness direction so as to cover the frame wiring 132, the wiring 134, and the joint wirings 1341, 1342, 1343, and 1344.

For example, the resin is applied to one surfaces of the metal supporting board 110, the base insulating layer 12, and the wiring layer 13, and the cover insulating layer 14 having the pattern corresponding to the frame 2, the mounting portion 3, and the joint 4 is formed by the photolithography. In this step, the cover insulating layer 14 of the frame 2, the cover insulating layer 14 of the mounting portion 3, and the cover insulating layer 14 of the joint 4 are formed simultaneously.

As shown in FIG. 4D, an outer shape of the metal supporting board 110 is processed, thereby forming the metal supporting layer 11. Examples of the outer shape processing include etching, punching, and laser. As the outer shape processing, preferably, from the viewpoint of productivity, etching is used. The metal supporting board 110 between the frame 2 and the mounting portion 3 is removed by the outer shape processing of the metal supporting board 110. Thus, the joint 4 does not include the metal supporting layer 11.

As shown in FIG. 4E, the imaging element 5 is mounted on the mounting portion 3. An electrode 51 of the imaging element 5 is electrically connected to the plurality of terminals 133 in the mounting portion 3. It is possible to mount the imaging element 5 on the mounting portion 3 via a mounting board which is not shown.

In addition, an external board 6 is mounted on the frame 2. An electrode 61 of the external board 6 is electrically connected to the plurality of frame terminals 131 in the frame 2. An outer side 24 of the frame 2 (ref: FIG. 1) may be also supported by an outer member (not shown).

### 2. Function and Effect of one Embodiment

As shown in FIG. 3, in the wiring circuit board 1, the joint 4 does not include the metal supporting layer 11. Therefore, the rigidity of the joint 4 is reduced. As a result, it is possible to correct the swing of the mounting portion 3 with small force.

As shown in FIG. 2, in the wiring circuit board 1, the joint 4 is connected to the second portion 32 where the converging line 134B is disposed in the mounting portion 3. Therefore, in the joint 4, it is possible to suppress the spread of the connecting portion 45 connected to the second portion 32 in the intersecting direction (width direction). As a result, it is possible to reliably reduce the rigidity of the joint 4.

In the wiring circuit board 1, when the frame 2 is moved and the joint 4 is flexed, since the spread of the connecting portion 45 is suppressed, the difference between the force applied to the central portion in the width direction in the joint 4, and the force applied to one end portion in the width direction is reduced, and therefore, it is possible to accurately control the swing of the mounting portion 3.

In the wiring circuit board 1, since the ratio of the length of the connecting portion 45 in the direction along the side 33B to the length of the side 33B is 0.3 or less, the spread of the connecting portion 45 is suppressed. Therefore, it is possible to reliably reduce the rigidity of the joint.

In the wiring circuit board, since the joint 4 is connected to the central region 34, it is possible to accurately control the swing of the mounting portion 3.

As shown in FIG. 1, since the joint 4 is connected to the central portion 35, it is possible to accurately control the swing of the mounting portion 3.

As shown in FIG. 3, in the wiring circuit board 1, since the base insulating layer 12 and the cover insulating layer 14 in the joint 4 have the slits 421, 422, and 423, it is possible to further reduce the rigidity of the joint 4.

In the wiring circuit board 1, since each of the wiring body portions 431 and 432 includes the four joint wirings 1341, 1342, 1343, and 1344, the joint wirings 1341, 1342, 1343, and 1344 can function as the differential wirings.

As shown in FIG. 1, in the wiring circuit board 1, since the joint 4 has the curved shape, it is possible to improve the accuracy of the swing correction as compared with the embodiment having the linear shape and/or the bent shape.

In the wiring circuit board 1, since the joint 4A connects the side 33B to the side 23A as the non-facing side which does not face the side 33B, it is possible to make the joint 4A longer. Therefore, the rigidity of the joint 4A is reduced.

### 3. Modified Examples

In each modified example below, the same reference numerals are provided for members and steps corresponding to each of those in the above-described one embodiment, and their detailed description is omitted. Further, each modified example can achieve the same function and effect as that of one embodiment unless otherwise specified. Furthermore, one embodiment and each modified example can be appropriately used in combination.

### 3.1 First Modified Example

As shown in FIG. 5, the joint 4A is connected to a first position 36 at the side 33B. The first position 36 is deviated from the central portion 35 to the side 33C-side in the central region 34. The first position 36 is included in the central region 34.

3.2 Second Modified Example

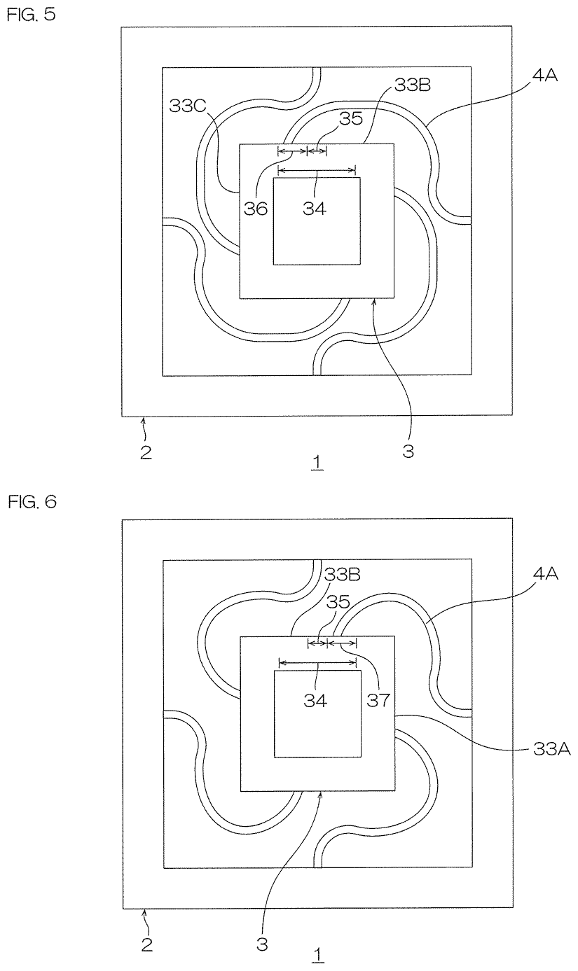

As shown in FIG. 6, the joint 4A is connected to a second position 37 at the side 33B. The second position 37 is deviated from the central portion 35 to the side 33A-side in the central region 34. The second position 37 is included in the central region 34.

Of one embodiment, the first modified example, and the second modified example, preferably, one embodiment is used. In one embodiment, since the joint 4A is connected to the central portion 35 of the side 33B, it is possible to accurately control the swing of the mounting portion 3.

### 3.3 Third Modified Example

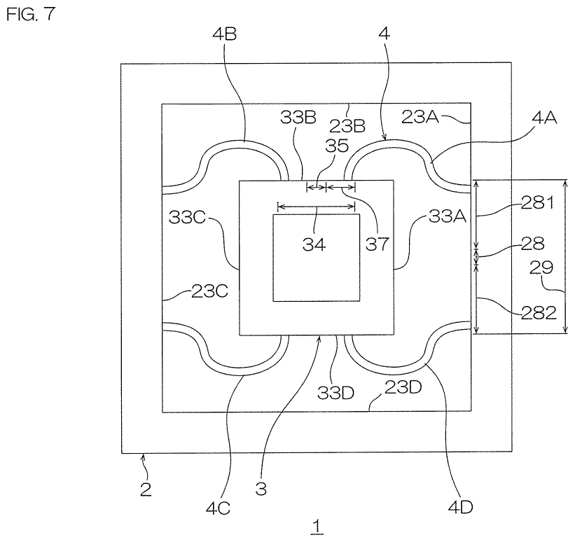

As shown in FIG. 7, the joint 4A is connected to a third position 281 at the side 23A. The third position 281 is deviated from the second central portion 28 to the side 23B-side in the second central region 29. The joint 4A is connected to the second position 37 at the side 33B in the same manner as the second modified example (FIG. 6).

The joint 4D is connected to a fourth position 282 at the side 23A. The fourth position 282 is deviated from the second central portion 28 to the side 23D-side in the second central region 29.

The joint 4B connects the side 23C of the frame 2 to the side 33B of the mounting portion 3. The joint 4D connects the side 23A of the frame 2 to the side 33D of the mounting portion 3.

That is, in the third modified example, each of the joints 4A and 4D is connected to the side 23A of the frame 2. Each of the joints 4B and 4C is connected to the side 23C of the frame 2.

In the third modified example, each of the joints 4A and 4B is connected to the side 33B of the mounting portion 3. Each of the joints 4C and 4D is connected to the side 33D of the mounting portion 3.

### 3.4 Fourth Modified Example

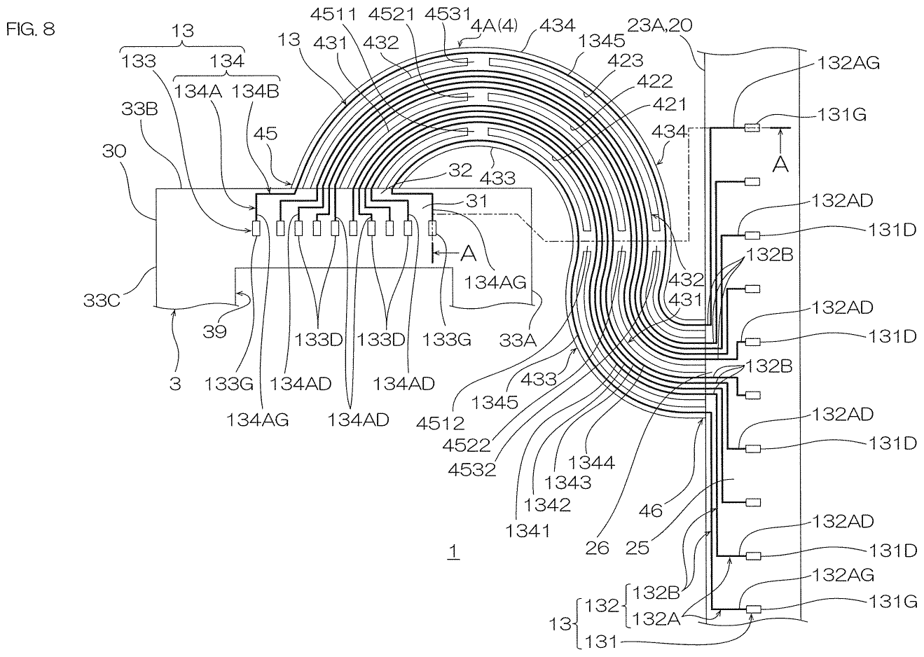

In the fourth modified example, as shown in FIG. 8, the joint 4 includes sub-joints 4511, 4512, 4521, 4522, 4531, and 4532.

The sub-joints 4511 and 4512 divide the slit 421 in the direction in which the slit 421 extends. The sub-joints 4511 and 4512 are spaced apart from each other in the direction in which the slit 421 extends.

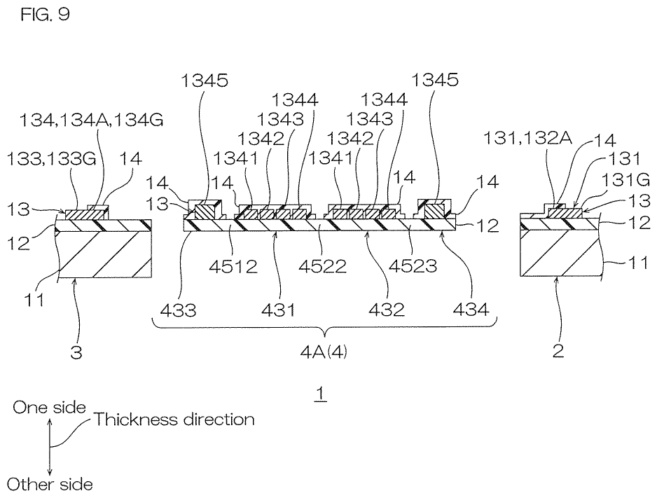

The sub-joints 4521 and 4522 divide the slit 422 in the direction in which the slit 422 extends. The sub-joints 4521 and 4522 are spaced apart from each other in the direction in which the slits 422 extend. As shown in FIG. 9, each of the sub-joints 4521 and 4522 connects the wiring body portion 431 to the wiring body portion 432. Further, each of the sub-joints 4521 and 4522 connects the joint wiring 1344 of the wiring body portion 431 to the joint wiring 1341 of the wiring body portion 432.

As shown in FIG. 8, the sub-joints 4511, 4521, and 4531 are disposed in the direction intersecting the direction in which the joint 4 extends (intersecting direction, preferably, orthogonal direction). The sub-joints 4512, 4522, and 4532 are disposed in the direction intersecting the direction in which the joint 4 extends (intersecting direction, preferably, orthogonal direction).

The sub-joints 4531 and 4532 divide the slit 423 in the direction in which the slit 421 extends. The sub-joints 4531 and 4532 are spaced apart from each other in the direction in which the slit 423 extends.

As shown in FIG. 9, the sub-joints 4511, 4512, 4521, 4522, 4531, and 4532 include the base insulating layer 12. In this modified example, the sub-joints 4511, 4512, 4521, 4522, 4531, and 4532 include only the base insulating layer 12.

According to the fourth modified example, it is possible to suppress an excessive reduction of the rigidity of the joint 4 caused by the slit 422 by the sub-joints 4521 and 4522. Therefore, it is possible to suppress an excessive deformation of the joint 4.

### 3.5 Fifth Modified Example

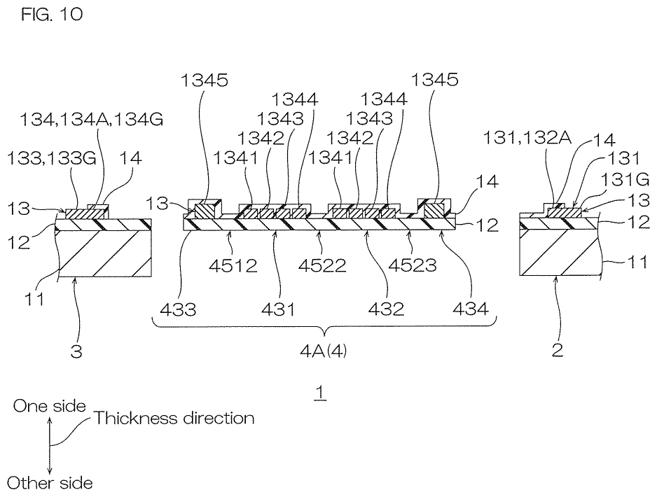

As shown in FIG. 10, the sub-joints 4511, 4512, 4521, 4522, 4531, and 4532 include the base insulating layer 12 and the cover insulating layer 14. In this modified example, the sub-joints 4511, 4512, 4521, 4522, 4531, and 4532 include only the base insulating layer 12 and the cover Although not shown, the sub-joints 4511, 4512, 4521, 4522, 4531, and 4532 may also include only the cover insulating layer 14.

### 3.6 Sixth Modified Example

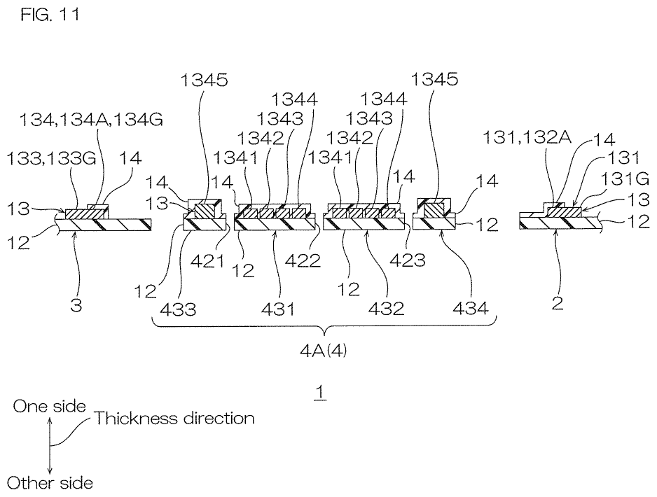

As shown in FIG. 11, each of the frame 2, the mounting portion 3, and the joint 4 does not include the metal supporting layer 11.

In the sixth modified example, since the frame 2 is supported by the external board 6 and an external member (not shown), and the mounting portion 3 is supported by the imaging element 5, the rigidity of the joint 4 with respect to the rigidity of each of the frame 2 and the mounting portion 3 is low. Therefore, it is possible to correct the swing of the mounting portion 3 with the small force.

### 3.7 Another Modified Example

Although not shown, the mounting portion 3 may not have the second portion 32. In this case, the joint 4A is connected to the first portion 31 of the mounting portion 3.

Preferably, the mounting portion 3 bas the second portion 32, and the joint 4A is connected to the second portion 32 of the mounting portion 3 in the same manner as one embodiment. In one embodiment, in the joint 4, it is possible to suppress the spread of the connecting portion 45 connected to the second portion 32 in the intersecting direction (width direction). As a result, it is possible to reliably reduce the rigidity of the joint 4.

In one embodiment, the mounting portion 3 has the rectangular frame shape. Alternatively, the mounting portion 3 may also have the rectangular shape without the inner peripheral edge 39.

The mounting portion 3 may also have the curved shape, and further, may also have the circular shape. In this case, the outer peripheral edge 30 of the mounting portion 3 does not have the side.

The frame 2 may also have the curved shape, and further, may also have an annular shape. In this case, the inner peripheral edge 20 of the frame 2 does not have the side.

The joint 4A may also have a generally wavy shape.

The number of joints 4 may be also two.

The joint 4 may have also have the linear shape and/or the bent shape.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### INDUSTRIAL APPLICATION

The wiring circuit board of the present invention is, for example, provided in an imaging device.

### DESCRIPTION OF REFERENCE NUMERALS

1 Wiring circuit board
2 Frame
3 Mounting portion
4, 4A, 4B, 4C, 4D Joint
11 Metal supporting layer
12 Base insulating layer
13 Wiring layer
14 Cover insulating layer
23A, 23B, 23C, 23D Side
30 Outer peripheral edge
31 First portion
32 Second portion
33, 33A, 33B, 33C, 33D Side
34 Central region
35 Central portion
45 Connecting portion
133, 133B Terminal
134 Wiring
421, 422, 423 Slit
431,432 Wiring body portion
4511, 4512, 4521, 4522, 4531, 4532 Sub-joint
1341, 1342, 1343, 1344 Joint wiring
1345 Ground wiring

1. A wiring circuit board comprising:
a frame, a mounting portion surrounded by the frame and being spaced apart from the frame, and a joint connecting the frame to the mounting portion, wherein
each of the frame and the mounting portion includes a base insulating layer, a wiring layer disposed on one surface of the base insulating layer in a thickness direction, and a cover insulating layer disposed on one surface of the base insulating layer in the thickness direction and covering a portion of the wiring layer, and may include a metal supporting layer disposed on the other surface of the base insulating layer in the thickness direction; and
the joint does not include the metal supporting layer, and includes the base insulating layer, the wiring layer, and the cover insulating layer.

2. The wiring circuit board according to claim 1, wherein
the wiring layer in the mounting portion includes a plurality of terminals spaced apart from each other, and a plurality of wirings spaced apart from each other and electrically connected to the plurality of terminals;
the joint includes a plurality of joint wirings spaced apart from each other and electrically connected to the plurality of wirings;
the mounting portion has a first portion in which the plurality of wirings extend from the plurality of terminals, and a second portion disposed between the first portion and an outer peripheral edge of the mounting portion and in which the plurality of wirings converge; and
the joint is connected to the second portion.

3. The wiring circuit board according to claim 1, wherein
the mounting portion has a side at an outer peripheral edge of the mounting portion,
the joint includes a connecting portion to which the joint is connected at the side, and
a ratio (length of the connecting portion/length of the side) of a length of the connecting portion in a direction along the side to the length of the side is 0.3 or less.

4. The wiring circuit board according to claim 1, wherein
the mounting portion has the side at the outer peripheral edge of the mounting portion; and
the joint is connected to a central region including a central portion at the side, and having a length of a half of the length of the side.

5. The wiring circuit board according to claim 3, wherein
the joint is connected to a central region including a central portion at the side, and having a length of a half of the length of the side.

6. The wiring circuit board according to claim 4, wherein
the joint is connected to the central portion of the side.

7. The wiring circuit board according to claim 1, wherein
the mounting portion has a plurality of sides at the outer peripheral edge of the mounting portion,
the plurality of joints are provided corresponding to the plurality of sides, and
of the plurality of joints, a difference in length between the longest joint and the shortest joint is 3 mm or less.

8. The wiring circuit board according to claim 1, wherein
the wiring layer in the joint has a plurality of joint wirings spaced apart from each other, and
the base insulating layer and the cover insulating layer in the joint have a slit disposed between the plurality of joint wirings.

9. The wiring circuit board according to claim 8, wherein
the slit extends along the plurality of joint wirings, and
the joint has a sub-joint dividing the slit in a direction in which the slit extends and connecting the plurality of joint wirings.

10. The wiring circuit board according to claim 8, wherein
the joint includes a plurality of wiring body portions divided by the slit, and the one wiring body portion includes at least two joint wirings.

11. The wiring circuit board according to claim 10, wherein
the slit extends along the plurality of wiring body portions, and
the joint has a sub-joint dividing the slit in a direction in which the slit extends and connecting the plurality of wiring body portions.

12. The wiring circuit board according to claim 1, wherein
the wiring layer in the joint includes a ground wiring electrically connected to the metal supporting layer.

13. The wiring circuit board according to claim 1, wherein
the joint has a curved shape.

14. The wiring circuit board according to claim 1, wherein
the mounting portion has a generally rectangular shape, and has a side at the outer peripheral edge of the mounting portion,
the frame has a generally rectangular frame shape, and has a facing side facing the side and a non-facing side adjacent to the facing side and not facing the side; and
the joint connects the side to the non-facing side.

15. The wiring circuit board according to claim 3, wherein
the mounting portion has a generally rectangular shape;
the frame has a generally rectangular frame shape, and has a facing side facing the side and a non-facing side adjacent to the facing side and not facing the side; and
the joint connects the side to the non-facing side.
